(19) United States
(12) Patent Application Publication
(10) Pub. No.: US 2026/0282644 A1
(43) Pub. Date: Sep. 17, 2026

(54) COMPOSITION AND METHOD FOR MANUFACTURING LIGHT-EMITTING ELEMENT USING SAME

(71) Applicant: Sharp Display Technology Corporation, Kameyama City, Mie (JP)

(72) Inventors: Takahiro ADACHI, Sakai City, Osaka (JP); Sentaro KIDA, Sakai City, Osaka (JP); YASUSHI ASAOKA, Sakai City, Osaka (JP)

(21) Appl. No.: 19/121,726

(22) PCT Filed: Oct. 19, 2022
(86) PCT No.: PCT/JP2022/038895

§ 371 Date: Apr. 16, 2025

(51) Int. Cl. H10K 50/115; H10K 71/15; H10K 85/10

(52) U.S. Cl. CPC H10K 50/115; H10K 71/15; H10K 85/146; H10K 85/151

(57) ABSTRACT

There is provided a photoresist capable of forming a photoresist layer having both developability and polar solvent resistance while having high peeling and removing properties as a positive-working photoresist layer. A composition constituting the photoresist includes a water-soluble resin, a positive-working photosensitizer, and a solvent, and the water-soluble resin includes a copolymer containing a vinyl alcohol monomer unit.

### TECHNICAL FIELD

The disclosure relates to a composition and a method for manufacturing a light-emitting element using the same. More specifically, the disclosure relates to a composition containing a water-soluble resin copolymer and a diazoquinone compound, and a method for manufacturing a light-emitting element using the same.

### BACKGROUND ART

PTL 1 describes a positive-working photosensitive composition for preparing a positive-working image forming material, which contains a water-insoluble organic solvent-soluble o-diazonaphthoquinone-based compound as a positive-working photosensitizer, a polyvinylpyrrolidone-based compound as a binder, and a stannic halide as a stabilizer, and which is dissolved in an organic solvent to be used.

### CITATION LIST

### Patent Literature

PTL 1: JP 05-011405 A

### SUMMARY

### Technical Problem

However, in the positive-working photosensitive composition as described in PTL 1, in the manufacture of a coating lamination type device exemplified by an organic EL or the like, an unexposed portion after patterning is easily dissolved in a polar solvent, and there is a problem in developability of a pattern. On the other hand, for example, a negative-working photosensitive composition has higher polar solvent resistance to a polar solvent of an exposed portion than a positive-working photosensitive composition, but there is a problem in that it is difficult to peel off and remove the composition after patterning.

Accordingly, there is a demand for a positive-working photosensitive composition capable of forming a photoresist layer having high polar solvent resistance without impairing peeling and removing properties.

An aspect of the disclosure has been made in view of the above-described problems, and is directed to providing a composition that is suitable for lift-off patterning of a polar solvent-based function layer material and can be used as a photoresist having both developability and polar solvent resistance while having high peeling and removing properties as a positive-working photoresist, and a technique related thereto.

### Solution to Problem

To solve the above problems, a composition according to an aspect of the disclosure includes: a water-soluble resin; a positive-working photosensitizer; and a solvent, in which the water-soluble resin includes a vinyl alcohol monomer unit and a monomer unit having water solubility.

A method for manufacturing a light-emitting element according to an aspect of the disclosure includes: applying the composition onto a substrate; exposing the applied composition to light; cleaning the exposed composition with a developer to develop a pattern of the composition on the substrate; forming a light-emitting layer on the substrate on which the pattern is developed; and peeling and developing, with a solvent, the composition remaining on the substrate on which the light-emitting layer is formed.

### Advantageous Effects of Disclosure

According to an aspect of the disclosure, it is possible to provide a composition capable of forming a photoresist layer having both developability and polar solvent resistance while having high peeling and removing properties as a positive-working photoresist layer.

### BRIEF DESCRIPTION OF DRAWINGS

FIG. 1 is a cross-sectional view schematically illustrating a step included in a method for manufacturing a light-emitting element according to a second embodiment of the disclosure.

FIG. 2 is a cross-sectional view schematically illustrating a step of forming a photoresist layer 50, included in the method for manufacturing a light-emitting element according to the second embodiment of the disclosure.

FIG. 3 is a cross-sectional view schematically illustrating a step of exposing the photoresist layer 50 to light, included in the method for manufacturing a light-emitting element according to the second embodiment of the disclosure.

FIG. 4 is a cross-sectional view schematically illustrating a step of developing a pattern on the exposed photoresist layer 50, included in the method for manufacturing a light-emitting element according to the second embodiment of the disclosure.

FIG. 5 is a cross-sectional view schematically illustrating a step of forming a first light-emitting layer 70R, included in the method for manufacturing a light-emitting element according to the second embodiment of the disclosure.

FIG. 6 is a cross-sectional view schematically illustrating a step of peeling and developing the first light-emitting layer 70R, included in the method for manufacturing a light-emitting element according to the second embodiment of the disclosure.

FIG. 7 is a cross-sectional view schematically illustrating a step of forming a photoresist layer 51 (second step of forming a composition), included in the method for manufacturing a light-emitting element according to the second embodiment of the disclosure.

FIG. 8 is a cross-sectional view schematically illustrating a step of exposing the photoresist layer 51 to light (second exposing step), included in the method for manufacturing a light-emitting element according to the second embodiment of the disclosure.

FIG. 9 is a cross-sectional view schematically illustrating a step of developing a pattern on the photoresist layer 51 (second developing step), included in the method for manufacturing a light-emitting element according to the second embodiment of the disclosure.

FIG. 10 is a cross-sectional view schematically illustrating a step of forming a second light-emitting layer 70B (second step of forming a light-emitting layer), included in the method for manufacturing a light-emitting element according to the second embodiment of the disclosure.

FIG. 11 is a cross-sectional view schematically illustrating a step of peeling and developing the second light-emitting layer 70B (second peeling and developing step), included in the method for manufacturing a light-emitting element according to the second embodiment of the disclosure.

FIG. 12 is a cross-sectional view schematically illustrating a step of forming a photoresist layer 52 (third step of forming a composition), included in the method for manufacturing a light-emitting element according to the second embodiment of the disclosure.

FIG. 13 is a cross-sectional view schematically illustrating a step of exposing the photoresist layer 52 to light (third exposing step), included in the method for manufacturing a light-emitting element according to the second embodiment of the disclosure.

FIG. 14 is a cross-sectional view schematically illustrating a step of developing a pattern on the photoresist layer 52 (third developing step), included in the method for manufacturing a light-emitting element according to the second embodiment of the disclosure.

FIG. 15 is a cross-sectional view schematically illustrating a step of forming a third light-emitting layer 70G (third step of forming a light-emitting layer), included in the method for manufacturing a light-emitting element according to the second embodiment of the disclosure.

FIG. 16 is a cross-sectional view schematically illustrating a step of peeling and developing the third light-emitting layer 70G (third peeling and developing step), included in the method for manufacturing a light-emitting element according to the second embodiment of the disclosure.

FIG. 17 is a cross-sectional view schematically illustrating a display device 200 including a plurality of light-emitting elements 100R, 100B, and 100G manufactured by the method for manufacturing a light-emitting element according to the second embodiment of the disclosure.

### DESCRIPTION OF EMBODIMENTS

### First Embodiment: Positive-Working Photosensitive Composition

Hereinafter, an embodiment of the disclosure will be described in detail.

A positive-working photosensitive composition (composition) according to an embodiment of the disclosure contains a water-soluble resin, a diazoquinone compound, and a solvent, and may contain other materials.

### Water-Soluble Resin

The water-soluble resin is a thermoplastic resin having water solubility, is a water-soluble resin that dissolves in pure water and an alkaline aqueous solution, and may contain a copolymer containing a vinyl alcohol monomer unit. The water-soluble resin is a copolymer containing two or more types of monomer units of a vinyl alcohol monomer unit and another monomer unit, and the vinyl alcohol monomer unit and another monomer unit are monomer units derived from monomers having water solubility.

The content of the vinyl alcohol monomer unit contained in the water-soluble resin is preferably from 35 to 90 mol % or more. When the content of the vinyl alcohol monomer unit is in the range of 35 to 90 mol % or more, developability and polar solvent resistance of a photoresist layer formed of the positive-working photosensitive composition can be controlled. The water-soluble resin only need be a copolymer containing a vinyl alcohol monomer unit, and the monomer unit other than the vinyl alcohol monomer unit contained in the copolymer only need be, for example, a monomer unit constituting a second polymer unit to be described below.

Water solubility of the water-soluble resin may be adjusted by substituting a part of hydrogen in a hydroxyl group of the polymer unit obtained by polymerization of the vinyl alcohol monomer unit, that is, the vinyl alcohol polymer unit, with a hydrophobic group. Here, examples of the hydrophobic group include an epoxy group and a (meth)acryloyl group.

The water-soluble resin only need be a copolymer of a vinyl alcohol monomer unit and another monomer unit having water solubility, and is preferably a block copolymer or a graft copolymer including a vinyl alcohol polymer unit obtained by polymerization of a vinyl alcohol monomer unit and a polymer unit derived from a monomer unit having water solubility other than the vinyl alcohol polymer unit, and more preferably a graft copolymer. When the water-soluble resin is a copolymer of two or more types of monomer units such as a block copolymer or a graft copolymer containing a vinyl alcohol polymer unit and another polymer unit, the film-forming properties of the water-soluble resin can be suitably controlled by difference in water solubility between the monomer units, which can control developability and polar solvent resistance of a photoresist layer to be described below. In addition, the photoresist layer can be provided with high peeling and removing properties as a positive-working photoresist layer.

In a case where the water-soluble resin is a block copolymer or a graft copolymer, a first polymer unit may be a vinyl alcohol polymer unit, and the water-soluble resin may be designed using a ratio of the vinyl alcohol polymer unit and a polymer unit having relatively different water solubility (hereinafter, referred to as a second polymer unit). More specifically, for example, the total molar amount of the monomer units contained in the first polymer unit and the second polymer unit is assumed to be 1.0, and a proportion occupied by the molar amount of the monomer unit contained in the first polymer unit is adjusted, whereby it is possible to control film forming properties in the water-soluble resin. Thus, the developability and the polar solvent resistance of the photoresist layer to be described below can be controlled.

When a vinyl alcohol polymer unit is adopted as the first polymer unit contained in the water-soluble resin, the ratio thereof is described as a polyvinyl alcohol (PVA) ratio. The PVA ratio is preferably from 0.3 to 0.9. When the PVA ratio is larger than 0.3, the polar solvent resistance in an unexposed portion of the photoresist layer formed of the positive-working photosensitive composition is enhanced. Thus, the unexposed portion of the photoresist layer can be prevented from being excessively removed by a developer. When the PVA ratio is smaller than 0.9, it is possible to prevent the water-soluble resin from excessively remaining and to enhance developability of an exposed portion of the photoresist layer. The ratio between the vinyl alcohol polymer unit and the second polymer unit in the block copolymer or the graft copolymer may be adjusted in line with the value of the PVA ratio of 0.3 to 0.9.

The water solubility of the second polymer unit of the water-soluble resin can be determined to be a solubility parameter (SP value) of the water-soluble resin. An approximate value of an SP value only need be roughly estimated from the SP value of the monomer contained in the water-soluble resin.

The SP value of the second polymer unit can be divided into three terms as shown in the following equation (1).

$$δ ( solubility parameter ) = {( {δ}_{D}^{2} + {δ}_{P}^{2} + {δ}_{H}^{2} )}^{1 / 2} \qquad ( 1 )$$

(In the equation (1), δ_{D} is a dispersion term, δ_{P} is a polar term, and δ_{H} is a hydrogen bonding term.)

Among the parameters shown in the equation (1), the polymer unit of the water-soluble resin preferably has a polar term δ_{P} of 5.0 or more from the viewpoint of increasing the resistance to dissolution in an alkaline aqueous developer (also an example of the polar solvent resistance) while increasing the polar solvent resistance of the photoresist layer in an organic solvent developer. The polar term δ_{P} only need be obtained from, for example, Hansen solubility parameter estimation software, and only need be roughly estimated from the polar term op of the monomer constituting the water-soluble resin and the molar ratio of the monomer unit contained in the water-soluble resin.

The type of the monomer unit constituting the second polymer unit contained in the water-soluble resin only need be selected depending on the water solubility of a homopolymer of each monomer unit. The water solubility of a homopolymer of each monomer unit only need be roughly estimated with reference to the SP value of the homopolymer or the SP value of the monomer. In a case where the water-soluble resin is a block copolymer or a graft copolymer, a polymer unit having relatively low water solubility may be referred to as a first polymer unit, and a polymer unit having relatively high water solubility may be referred to as a second polymer unit. The difference (difference in SP value) between the water solubility of the first polymer unit and the water solubility of the second polymer unit is preferably large. Note that the SP value of the polyvinyl alcohol as the first polymer unit is 12.6, and this SP value is referred to as the SP value of a homopolymer.

The monomer constituting the second polymer unit only need have, for example, an SP value of 9.0 or more, and preferably 25.8 or more. Examples of such a monomer include (meth)acrylic acid (SP value: 9.6), (meth)acrylic acid salt, (meth)acrylamide (SP value: 9 to 15), and N-vinylacetamide (SP value: 10.9), and more preferably N-vinylpyrrolidone (SP value: 26.2). The SP value of the monomer constituting the second polymer unit is not limited, and may be, for example, 30.0 or less. Examples of the monomer unit derived from these monomers include a monomer unit derived from (meth)acrylic acid, a monomer unit derived from (meth)acrylic acid salt, a monomer unit derived from (meth)acrylamide, and a monomer unit derived from N-vinylacetamide. Besides, examples of the monomer unit include monomer units such as an ethylene oxide unit, a propylene oxide unit, an ethylene amine unit, and propylene amine unit. The water-soluble monomer unit constituting the second polymer unit may be, for example, a monomer unit derived from a monomer having a hydrophilic group such as a carboxyl group, a hydroxyl group, an amino group, or an amide group, or may be a monomer unit forming a hydrophilic main chain exemplified by a polyether chain such as polyethylene glycol, a polyamine chain such as spermine or spermidine, or the like by polymerization.

In the present specification, “(meth)acrylic acid” includes the meaning of both “acrylic acid” and “methacrylic acid”, and “(meth)acrylamide” includes the meaning of both “acrylamide” and “methacrylamide”.

### Positive-Working Photosensitizer

The positive-working photosensitizer only need be, for example, a compound which is decomposed (also referred to as depolymerized) by irradiation with light to generate a proton (H⁺) and an organic compound having an acid group such as a carboxylic acid group or a sulfonic acid group. Examples of the organic compound having a carboxylic acid group include indenecarboxylic acid, phthalic acid, and derivatives thereof. The positive-working photosensitizer may typically be a diazoquinone compound. Thus, the positive-working photosensitizer will be described below by using a diazoquinone compound which is a typical example. Examples of the diazoquinone compound include diazoquinones such as diazobenzoquinone (DBQ) and diazonaphthoquinone (DNQ), and derivatives thereof.

When a diazoquinone compound is used as the positive-working photosensitizer, as will be described below, the peeling and removing properties of the photoresist layer by a solvent having a polar term δ_{P} of 5.0 or more is enhanced while enhancing the polar solvent resistance of the unexposed portion of the photoresist layer. In addition, when the diazoquinone compound is contained, high peeling and removing properties as a positive-working photoresist layer can be imparted.

The diazoquinone derivative only need be, for example, a compound in which a diazoquinone moiety and a residue derived from a compound having a hydroxyl group or an amino group are bonded via an ester bond or an amide bond. Here, the diazoquinone moiety only need have, for example, a sulfonyl group for forming an ester bond or an amide bond. The diazoquinone compound may be a compound having an ester bond or an amide bond derived from a sulfonyl group of the diazoquinone moiety and a hydroxyl group or an amino group of a compound. Here, the residue derived from a compound having a hydroxyl group means an alcohol residue, and the residue derived from a compound having an amino group means an amine residue.

In a case where the compound forming an ester bond or an amide bond with the diazoquinone moiety has a divalent or higher hydroxyl group or amino group, a conversion rate of the hydroxyl group or amino group of the compound by the diazoquinone moiety is preferably 30 mol % or more. In addition, although it should not be limited, the conversion rate of the hydroxyl group or the amino group of the compound by the diazoquinone moiety may be substantially 100 mol %. This makes it possible to suitably control the solubility of the photoresist layer in a developer before and after exposure to light, which can control the developability and the polar solvent resistance. The conversion rate by the diazoquinone moiety is defined as a conversion rate of a hydroxyl group contained in the compound into an ester bond or a conversion rate of an amino group contained in the compound into an amide bond, and is calculated by the following formula.

(Number of moles of diazoquinone moiety)/(number of moles of hydroxyl group and amino group of compound before conversion by diazoquinone moiety)×100

Examples of the derivative of diazoquinone include an azoquinone sulfonic acid ester and azoquinone sulfonic acid amide.

Examples of the diazoquinone sulfonic acid ester include diazobenzoquinone compounds such as 1,2-benzoquinone diazo-4-sulfonic acid ester and 1,2-benzoquinone diazo-5-sulfonic acid ester, and diazonaphthoquinone compounds such as 1,2-naphthoquinone diazo-5-sulfonic acid ester and 1,2-naphthoquinone diazo-4-sulfonic acid ester. The diazoquinone sulfonic acid derivative may be diazo-coupled.

In the diazoquinone compound, examples of a compound for forming a residue (alcohol residue) derived from a compound having a hydroxyl group include a compound having a phenolic hydroxyl group. The compound having a phenolic hydroxyl group may be a phenol having a monovalent hydroxyl group such as phenol or naphthol, a phenol having a divalent or higher hydroxyl group such as catechol or pyrogallol, a phenol having a divalent or higher phenolic hydroxyl group such as bisphenol, trisphenol or tetrakisphenol, or a phenol resin such as a novolac-type phenol resin. Examples of the compound having a phenolic hydroxyl group include 4,4′,4″-ethylidinetrisphenol, 2,3,4-trihydroxybenzophenone, 2,3,4,4′-tetrahydroxybenzophenone, α,α-bis(4-hydroxyphenyl)-4-(4-hydroxy-α,α-dimethylbenzyl)-ethylbenzene, 4,4′-(1-{4-[1-(4-hydroxyphenyl)-1-methylethyl]phenyl}ethylidene)diphenol, and a novolac-type cresol resin.

Examples of the diazoquinone sulfonamide as the diazoquinone compound include a compound in which a 1,2-benzoquinone diazo 4-sulfonyl group or the like is introduced into an amino group introduced into a resin by an ester bond between a hydroxyl group of an amino alcohol and a resin having a carboxyl group to form sulfonamide.

In the positive-working photosensitive composition, the content of the diazoquinone compound is suitably 15 mass % or more, preferably 30 mass % or more, more preferably 50 mass % or more, and still more preferably 70 mass % or more, per 100 mass % of the total of the water-soluble resin and the diazoquinone compound. Although it should not be limited, the content of the diazoquinone compound only need be 90 mass % or less.

The positive-working photosensitizer contained in the positive-working photosensitive composition is not limited to the diazoquinone compound described above. The positive-working photosensitizer only need be, for example, at least one positive-working photosensitizer selected from the group consisting of the above-described diazoquinone compound, polyolefin sulfone, and polyphthalaldehyde. The polyolefin sulfone only need be a polyolefin sulfone having photosensitivity, and may be, for example, a photosensitive polyolefin sulfone in which a dye that generates an amine by absorbing light is introduced into a side chain of the polyolefin sulfone via a carbon bonded to a sulfone group in a polyolefin sulfone chain. In addition, the polyphthalaldehyde only need be any polyphthalaldehyde having photosensitivity, and examples thereof include photosensitive polyphthalaldehydes such as polyphthalaldehyde (PPA) and a polyphthalaldehyde having an oxime ether terminal.

### Solvent

Examples of the solvent contained in the positive-working photosensitive composition include water, alcohols such as ethanol, isopropyl alcohol (IPA), and ethylene glycol, polar solvents such as N-methylpyrrolidone (NMP) and dimethyl sulfoxide (DMSO), nitriles such as acetonitrile, ketones such as acetone and methyl ethyl ketone, and polyethylene glycol monomethyl ether acetate (PEGMEA). Two or more types of these solvents may be used in combination.

### Crosslinking Agent

The positive-working photosensitive composition may contain a crosslinking agent. The crosslinking agent may be a crosslinking agent that is crosslinked by an acid generated when the diazoquinone compound contained in the positive-working photosensitive composition is exposed to light, and examples thereof include a novolac-type phenol resin, an epoxy resin, a melamine resin, an unsaturated polyester resin, a polyimide resin, diallyl phthalate, and a urethane resin. Thus, the degree of crosslinking can be controlled by controlling the content of the crosslinking agent and the firing conditions at the time of forming a photoresist layer, and the control of the solubility due to this exhibits an effect of being capable of obtaining a pattern with higher accuracy. In a case where the positive-working photosensitive composition contains the crosslinking agent, the content of the crosslinking agent should not be limited, but only need be, for example, more than 0 parts by mass, and is preferably 100 parts by mass or less, and more preferably 50 parts by mass or less, per 100 parts by mass of the total of the water-soluble resin and the diazoquinone compound.

### Other Additives

Besides, the composition for forming the photoresist layer may contain, as additives, for example, a photosensitizer such as acetophenone, a chemical sensitizer, a filler, a coloring agent, a stabilizer such as an antioxidant, and a surfactant such as a leveling agent, an antifoaming agent, or a dispersant.

Examples of the surfactant include fluorine-based solvents such as hydrofluoroether and hydrofluoroolefin, and fluorine-based surfactants having a hydrophobic group such as a hydrofluoroether chain or a hydrofluoroolefin chain and a hydrophilic group.

The dissolution rate of the photoresist layer, which is a coating film formed by applying the positive-working photosensitive composition, varies depending on the SP value and the polar term δₚ of the solvent. For example, the dissolution rate of the unexposed portion of the photoresist layer in dimethyl sulfoxide (polar term δₚ: 7.8) is preferably 10 nm/s or more, and more preferably 50 nm/s or more at room temperature (23° C.). The dissolution rate in dimethyl sulfoxide only need be, but is not limited to, 2000 nm/s or less.

The dissolution rate of the photoresist layer, which is a coating film formed of the positive-working photosensitive composition, in ethanol (polar term δₚ: 4.3) only need be 10 nm/s or less, and is more preferably 5 nm/s or more at room temperature (23° C.). The dissolution rate in ethanol only need be, but is not limited to, 20 nm/s or less. The evaluation of the dissolution rate in dimethyl sulfoxide and the dissolution rate in ethanol of the unexposed portion of the photoresist layer only need be performed in accordance with “Evaluation of Film Thickness Reduction Amount” described in Examples of the disclosure, and only need be calculated from the evaluation result of the film thickness reduction amount.

The photoresist layer formed of the positive-working photosensitive composition has enhanced polar solvent resistance to a polar solvent having a polar term δₚ of 5.0 or less exemplified by ethanol and the like as described below.

### Second Embodiment: Method for Manufacturing Light-Emitting Element

Another embodiment of the disclosure will be described below.

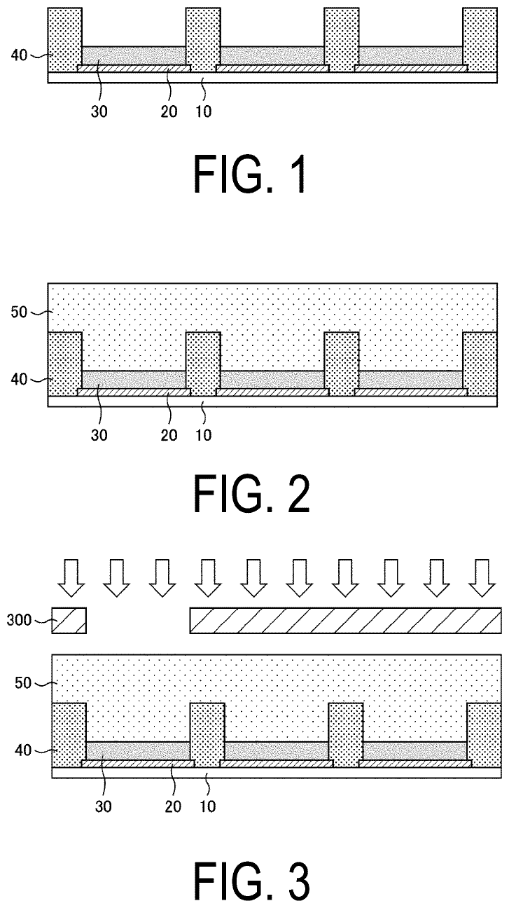

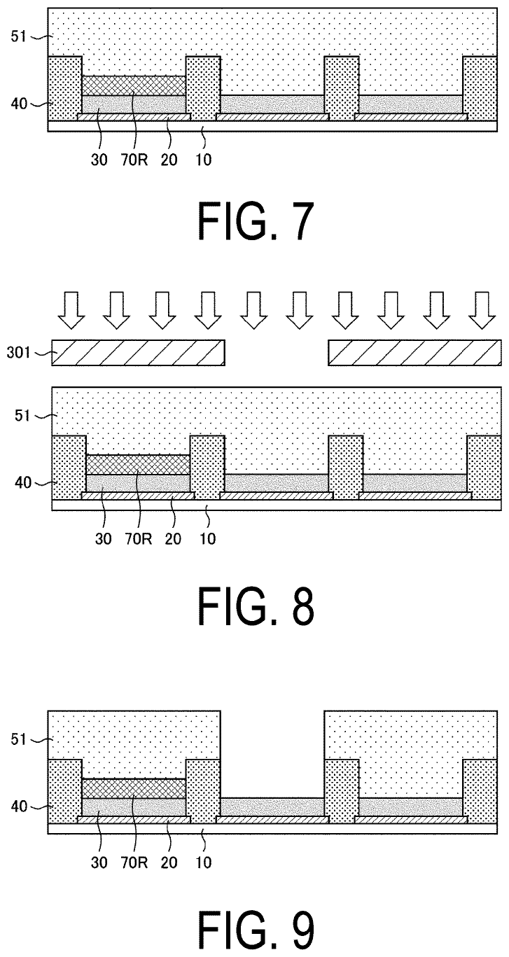

A method for manufacturing a light-emitting element according to an embodiment of the disclosure will be described with reference to FIGS. 1 to 17. As illustrated in FIGS. 1 to 17, a method for manufacturing a light-emitting element according to the embodiment of the disclosure includes: (i) a step of applying a positive-working photosensitive composition (composition) onto a substrate; (ii) a step of exposing the applied composition to light; (iii) a step of cleaning the exposed positive-working photosensitive composition with a developer to develop a pattern of the composition on the substrate; (iii) a step of forming a light-emitting layer on the substrate on which the pattern is developed; and (iv) a step of peeling and developing, with a solvent, the composition remaining on the substrate on which the light-emitting layer is formed. Thus, a light-emitting layer 70R is manufactured on a substrate 10. In addition, the steps of (i) to (iv) are repeated to manufacture light-emitting elements 100R, 100B, and 100G including a plurality of light-emitting layers 70R, 70B, and 70G on the substrate 10, and manufacture a display device 200 including the plurality of light-emitting elements.

As illustrated in FIG. 1, first electrodes 20 and first charge transport layers 30 are formed on a substrate 10 to be partitioned by banks 40.

The substrate 10 may be, for example, a resin substrate made of a resin material such as polyimide, or may be a glass substrate. In a case where a non-flexible display device is manufactured, the glass substrate can be used as the substrate.

The first electrodes 20 are not limited as long as they are anodes or cathodes, but are anodes in the present embodiment.

The first charge transport layers 30 are not limited as long as they are hole transport layers or electron transport layers, but are hole transport layers in the present embodiment. The first charge transport layers 30 which are hole transport layers only need be formed of a composition containing a hole injection material or a hole transport material which will be described below.

The banks 40 only need be formed in advance before forming electrodes to insulate the first electrodes 20 from each other.

FIG. 2 is a diagram schematically illustrating a step of forming a photoresist layer 50. The photoresist layer 50 is formed of the positive-working photosensitive composition according to an aspect of the disclosure.

The positive-working photosensitive composition is collectively applied to subpixels in the plurality of light-emitting elements by a dip coating method or a spin coating method, thereby providing the photoresist layer 50. Thereafter, the photoresist layer 50 only need be heated and dried, for example, at a temperature in a range of 80 to 150° C. Alternatively, the positive-working photosensitive composition is not limited to being collectively applied to the subpixels, and may be separately applied to each subpixel by, for example, an ink-jet method or the like. When the photoresist layer 50 is heated, diazo coupling of the diazoquinone compound can be promoted. This can increase the number of bonding points of the photoresist layer 50, which can enhance the polar solvent resistance. In addition, esterification is performed by a reaction between the hydroxyl group of the vinyl alcohol monomer unit and an acid compound formed of the diazo compound, which can enhance the polar solvent resistance.

After the photoresist layer 50 is heated and dried, as illustrated in FIG. 3, the photoresist layer 50 formed on the first charge transport layers 30 is preferably exposed to light using a photomask 300 having a desired pattern. Examples of the light for exposing the photoresist layer 50 to light include an ultraviolet ray having a wavelength of about 150 to 450 nm and an electron beam. The ultraviolet ray may be a g-line (wavelength 436 nm), an h-line (wavelength 405 nm), or an i-line (wavelength 365 nm) from a high-pressure mercury lamp, or may be an excimer laser (wavelength 150 to 248 nm). The amount of exposure is not limited, but only need be, for example, in a range of 1 mJ/cm² to 1000 mJ/cm². The photoresist layer 50 and the surfaces of the first charge transport layers 30 only need be sufficiently exposed to light in this manner.

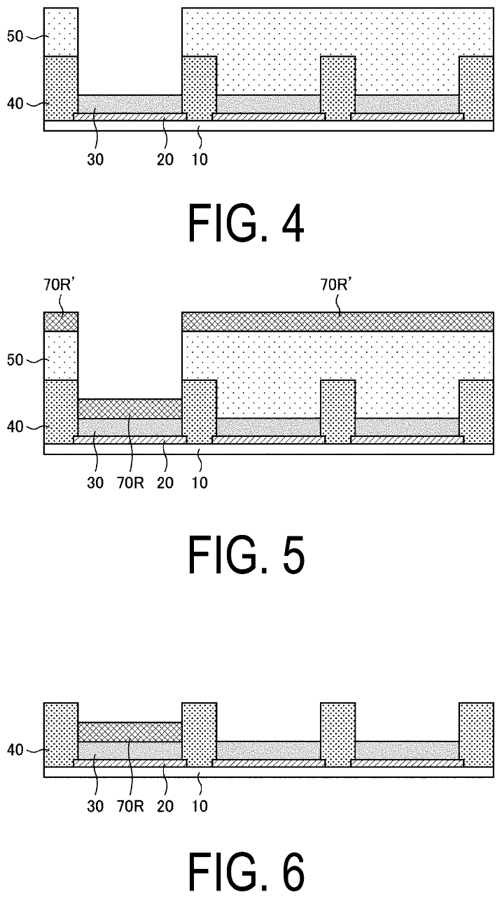

FIG. 4 is a diagram schematically illustrating a step of cleaning the photoresist layer 50 with a developer to develop a pattern in an exposed portion of the photoresist layer 50. In the photoresist layer 50, an acidic compound such as an indenecarboxylic acid derivative is generated in the exposed portion, thereby enhancing the solubility in an alkaline aqueous developer. Thus, a desired pattern can be developed on the photoresist layer 50 by cleaning with the alkaline aqueous developer. Here, the photoresist layer 50 remaining in the unexposed portion contains the water-soluble resin containing the polymer unit in which the vinyl alcohol monomer unit is polymerized, and has increased solvent resistance due to many bonding points of diazo coupling in the diazoquinone compound. Thus, it is possible to prevent the photoresist layer 50 from being excessively dissolved at the time of the developing treatment with the alkaline aqueous developer. In addition, the unexposed portion of the photoresist layer 50 has increased polar solvent resistance, and thus it is possible to obtain high developability capable of realizing a pattern with a clear contrast.

The desired pattern can be developed by, for example, immersing the photoresist layer 50 in a beaker (not illustrated) storing a developer. The developer may be supplied to the photoresist layer 50 by, for example, spraying the developer using a spray nozzle or the like.

The developer is preferably an alkaline aqueous developer, and examples of the alkaline aqueous developer include aqueous developers containing alkalis such as potassium hydroxide (KOH) and tetramethylammonium hydroxide (TMAH). An aqueous developer such as the alkaline aqueous developer is a water-based polar solvent even though the SP value and the polar term thereof are high, and the unexposed portion of the photoresist layer 50 also has enhanced polar solvent resistance to the alkaline aqueous developer.

The photoresist layer 50 after developing may be heated and dried, for example, at a temperature of 50 to 150° C.

FIG. 5 is a diagram schematically illustrating a step of forming a light-emitting layer 70R on the pattern formed on the photoresist layer 50. The light-emitting layer 70R may be formed by applying a composition containing a light-emitting material on the photoresist layer 50 on which the pattern has been formed. A light-emitting layer 70R′ is not different from a light-emitting layer 70R except that the light-emitting layer 70R′ is provided in the unexposed portion of the photoresist layer 50. In the step of forming the light-emitting layer, it is only necessary to form the light-emitting layer 70R, and the light-emitting layer 70R′ need not be necessarily formed.

The light-emitting layer can be film-formed by separately patterning for each subpixel by using a dispersion liquid in which quantum dots (QDs) are dispersed by a spin coating method, an ink-jet method, or the like. Examples of the dispersion solvent contained in the dispersion liquid of quantum dots (QDs) include a polar solvent (low-polar organic solvent) having an SP value of less than 12.0 and a polar term δₚ of less than 5.0. Examples of the dispersion solvent of quantum dots (QDs) include isopropyl ether (SP value: 7.0, polar term: 2.4), n-hexane (SP value: 7.3, polar term: 0.1), cyclohexane (SP value: 8.2, polar term: −0.2), carbon tetrachloride (SP value: 8.6, polar term: 1.6), ethyl acetate (SP value: 8.6, polar term: 4.4), toluene (SP value: 8.9, polar term: 2.4), tetrahydrofuran (SP value: 9.1, polar term: 4), chloroform (SP value: 9.3, polar term: 4.1), methylene chloride (SP value: 9.6, polar term: 3.1), ethylene dichloride (SP value: 9.7, polar term: 4.3), dioxane (SP value: 9.8, polar term: 4.8), isopropyl alcohol (SP value: 10.2, polar term: 3.9), and ethanol (SP value: 11.2, polar term: 4.3).

The water-soluble resin contains the above-described vinyl alcohol monomer unit and another monomer unit, and thus the photoresist layer 50 has an approximate SP value of 12.0 or more, and preferably has a polar term of 5.0 or more, whereby the photoresist layer 50 has high polar solvent resistance and it is possible to prevent unintentional dissolution by the dispersion solvent of the dispersion liquid in which the quantum dots (QDs) are dispersed.

FIG. 6 is a diagram schematically illustrating a step of removing the photoresist layer 50 by cleaning with the developer. In the peeling and developing step, the light-emitting layer 70R′ is peeled off from the substrate 10 by the developer together with the unexposed portion of the photoresist layer 50. Thus, the light-emitting layer 70R is developed into a desired pattern on the photoresist layer 50.

In the developer used in the peeling and developing step, the SP value of the solvent contained in the developer is preferably higher than 12, and the polar term δ_{P} calculated by the equation (1) above is more preferably 5.0 or more to completely dissolve the exposed portion of the photoresist layer 50. Examples of a solvent (highly-polar organic solvent) satisfying such conditions include dimethylformamide (SP value: 11.5, polar term: 6.4), methyl sulfoxide (SP value: 12.8, polar term: 7.2), acetonitrile (SP value: 11.8, polar term: 5.8), acetic acid (SP value: 12.4, polar term: 6), methanol (SP value: 12.9, polar term: 5.1), ethylene glycol (SP value: 14.7, polar term: 6.9), PEGMEA (SP value: 15.9, polar term: 4.7), N-methylpyrrolidone (SP value: 18, polar term: 12.3), and water (SP value: 21, polar term: 10.0). When the organic solvent developer is used as the developer, the unexposed portion of the photoresist layer 50 can be successfully peeled off together with the light-emitting layer 70R′ due to the high peeling and removing properties, and the light-emitting layer 70R can be developed to have a desired pattern.

The developer may be supplied to the photoresist layer 50 by immersion in a beaker storing the developer (developer tank) or by spraying the developer using a spray nozzle or the like.

FIG. 8 is a diagram illustrating an outline from a step of forming a photoresist layer 51 (second photoresist layer) to a step of exposing the photoresist layer 51 to light. A photomask 301 has a pattern different from that of the photomask 300 to avoid overlapping of a region to be patterned.

The method of applying a photosensitive composition for forming the photoresist layer 51 is the same as the method of applying the photosensitive composition for forming the photoresist layer 50, and thus the description thereof is omitted.

FIG. 9 is a diagram schematically illustrating a step of forming a pattern on the photoresist layer 51 (second photoresist layer). As in the first developing, an alkaline aqueous developer is preferably used. In the second developing step, the front surface of the light-emitting layer 70R is protected from the alkaline aqueous developer due to the polar solvent resistance of the photoresist layer 51 by being covered with the photoresist layer 51. In addition, the unexposed portion of the photoresist layer 51 has increased polar solvent resistance, and thus high developability can be obtained.

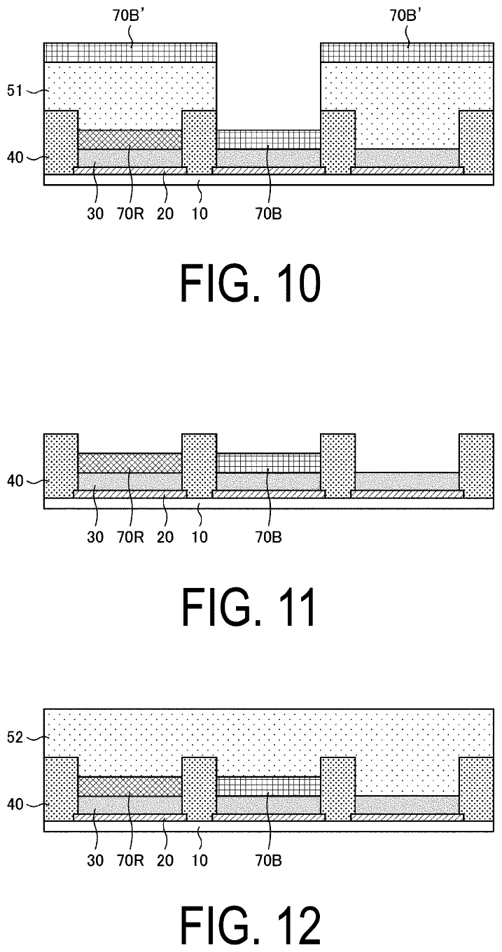

FIG. 10 is a diagram schematically illustrating a step of forming a light-emitting layer 70B. The light-emitting layer 70B is identical to the light-emitting layer 70R except that the light-emitting layer 70B emits light having a light emission central wavelength in a wavelength band of longer than 400 nm and 500 nm or shorter and is formed at a different position. A light-emitting layer 70B′ is not different from the light-emitting layer 70B except that the light-emitting layer 70B′ is formed in the unexposed portion of the photoresist layer 51.

FIG. 11 is a diagram schematically illustrating a step of removing the photoresist layer 51 by second cleaning with the developer. In the peeling and developing step, the light-emitting layer 70B′ is peeled off from the substrate 10 together with the unexposed portion by the developer due to the peeling and removing properties of the photoresist layer 51.

FIG. 12 is a diagram schematically illustrating a step of forming a photoresist layer 52 (third photoresist layer). The photoresist layer 52 may have the same composition as that of each of the photoresist layer 50 and the photoresist layer 51, or may have a different composition.

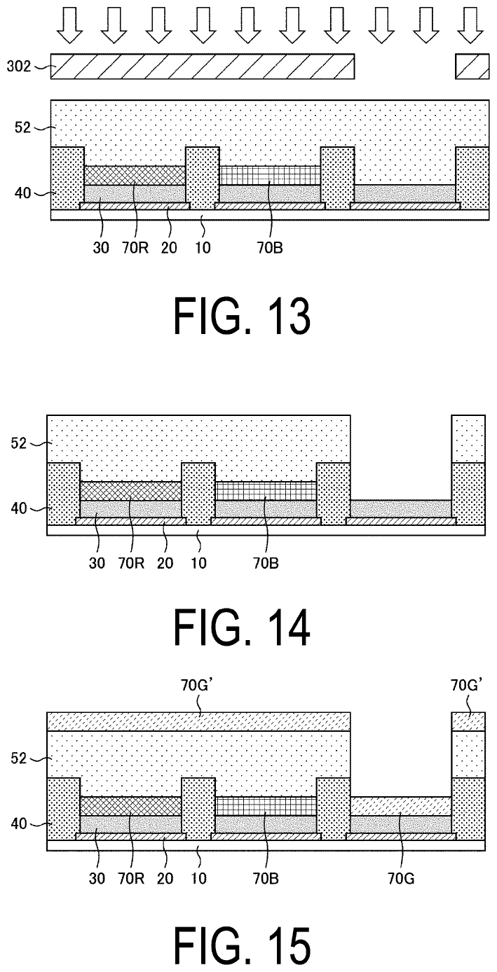

FIG. 13 is a diagram schematically illustrating a step of exposing the photoresist layer 52 (third photoresist layer) to light. A photomask 302 has a pattern different from that of each of the photomask 300 and the photomask 301 to avoid overlapping of light-emitting regions.

FIG. 14 is a diagram schematically illustrating a step of forming a pattern on the photoresist layer 52 (third photoresist layer). As in the first and second developing, an alkaline aqueous developer is preferably used. Note that here, front surfaces of the light-emitting layers 70R and 70B are covered with the photoresist layer 52 to be protected from the alkaline aqueous developer due to the polar solvent resistance of the photoresist layer 52. In addition, the unexposed portion of the photoresist layer 52 has increased polar solvent resistance, and thus high developability can be obtained.

FIG. 15 is a diagram schematically illustrating a step of forming a green light-emitting layer 70G. The light-emitting layer 70G is identical to the light-emitting layer 70R except that the light-emitting layer 70G emits light having a light emission central wavelength in a wavelength band of longer than 500 nm and 600 nm or shorter and is formed at a different position. A light-emitting layer 70G′ is not different from the light-emitting layer 70G except that the light-emitting layer 70G′ is formed in an unexposed portion of the photoresist layer 52.

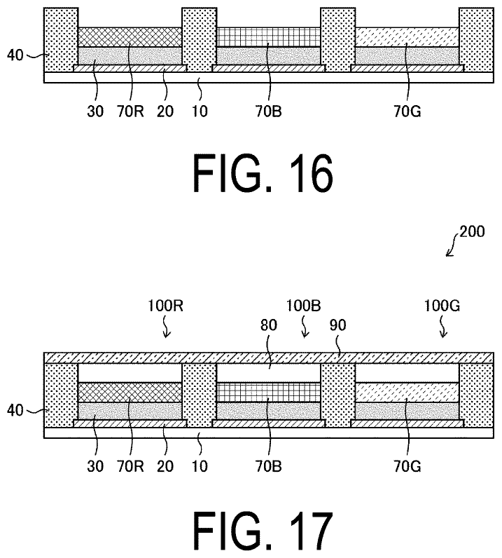

FIG. 16 is a diagram schematically illustrating a step of removing the photoresist layer 52 by third cleaning with the developer. In the peeling and developing step, the light-emitting layer 70G′ is peeled off from the substrate 10 by the developer together with the unexposed portion of the photoresist layer 52.

As illustrated in FIG. 17, second charge transport layers 80, which are electron transport layers, and a second electrode 90, which is a cathode, are formed on the substrate 10 on which the light-emitting layers 70R, 70B, and 70G have been formed. Thus, a display device 200 including a plurality of light-emitting elements including the light-emitting element 100R including the first electrode 20 which is an anode, the first charge transport layer 30 which is a hole transport layer, the light-emitting layer 70R, the second charge transport layer 80, and the second electrode 90 which is a cathode, the light-emitting element 100B including the light-emitting layer 70B instead of the light-emitting layer 70R, and the light-emitting element 100G including the light-emitting layer 70G instead of the light-emitting layer 70R is manufactured.

Although an embodiment in which the first electrode 20 is an anode has been described above, the first electrode is not limited to an anode in the method for manufacturing a light-emitting element according to an embodiment of the disclosure. The light-emitting element manufactured by the manufacturing method according to an embodiment may have a normal layered structure, but is not limited thereto and may have a reverse layered structure. Thus, the first charge transport layer may be an electron transport layer and the second charge transport layer may be a hole transport layer. That is, the light-emitting element may have a configuration in which a first electrode which is a cathode, a first charge transport layer which is an electron transport layer, a light-emitting layer, a second charge transport layer which is a hole transport layer, and a second electrode which is an anode are layered in this order on a substrate.

The light-emitting element may be a top-emitting type or a bottom-emitting type. To obtain a top-emitting type with a normal layered structure, the anode only need be formed using an electrode material that reflects visible light and the cathode only need be formed using an electrode material that transmits visible light. On the other hand, to obtain a bottom-emitting type, the anode only need be formed using an electrode material that transmits visible light and the cathode only need be formed using an electrode material that reflects visible light.

The electrode material that reflects visible light is not particularly limited as long as the material can reflect visible light and has electrical conductivity, and examples thereof include metal materials such as Al, Cu, Au, Mg, Li, and Ag, alloys of the metal materials, layered bodies of the metal materials and transparent metal oxides (for example, indium tin oxide, indium zinc oxide, indium gallium zinc oxide, and the like), or layered bodies of the alloys and the transparent metal oxides.

On the other hand, the electrode material that allows visible light to pass through is not particularly limited as long as the material can allow visible light to pass through and has electrical conductivity, and examples thereof include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

A general electrode forming method can be used as a film formation method of the first and second electrodes, and examples thereof include physical vapor deposition (PVD) methods such as a vacuum vapor deposition method, a sputtering method, an electron beam (EB) vapor deposition method, and an ion plating method, or a chemical vapor deposition (CVD) method. Furthermore, a method of patterning the first and second electrodes is not limited, and examples thereof include a photolithography method and an ink-jet method. The positive-working photosensitive composition according to an embodiment of the disclosure can also be suitably used for patterning the first and second electrodes.

Examples of the method for manufacturing a bank that surrounds the light-emitting layer include patterning by a photolithography method after applying an organic material such as polyimide or acrylic. The positive-working photosensitive composition according to an embodiment of the disclosure can also be suitably used for bank patterning.

The hole transport layer is a layer that transports positive holes toward the light-emitting layer. Although not illustrated, the hole transport layer may be composed of a plurality of hole transport layers. In a case where the light-emitting element includes a plurality of hole transport layers, one of the hole transport layers may be referred to as a hole injection layer.

In a case where the hole transport layer is a hole injection layer, examples of a hole injection material include a nanoparticle of NiO, CuI, Cu₂O, CoO, Cr₂O₃, or CuAlS₂. The nanoparticle which is a hole injection material may include thiol, amine, or the like as a ligand. These hole injection materials may be used as a dispersion liquid for forming the hole transport layer.

A material to be used for the hole transport layer is not particularly limited as long as the material is a hole transport material capable of stabilizing the transport of positive holes to the light-emitting layer. The hole transport material in the hole transport layer preferably has high hole mobility. Furthermore, the hole transport material is preferably a material (electron blocking material) capable of preventing the penetration of electrons that have traveled from the cathode. This makes it possible to increase a recombination efficiency of the holes and the electrons within the light-emitting layer. The hole transport material is preferably, for example, a photosensitive hole transport material having a cation polymerizable functional group such as an oxetane ring, and examples of the photosensitive hole transport material include N,N′-(4,4′-(cyclohexane-1,1-diyl)bis(4,1-phenylene))bis(N-(4-(6-(2-ethyloxetan-2-yloxy) hexyl)phenyl)-3,4,5-trifluoroaniline), N4,N4′-bis(4-(6-((3-ethyloxetan-3-yl) methoxy) hexyloxyphenyl)-N4,N4′-bis(4-methoxyphenyl) biphenyl-4,4′-diamine, and N4,N4′-bis(4-(6-((3-ethyloxetan-3-yl) methoxy) hexyl)phenyl)-N4,N4′-diphenylbiphenyl-4,4′-diamine. The photosensitive hole transport material included in the hole transport layer may be cationically polymerized by, for example, a photoacid generator or the like. In addition, the hole transport layer may include a product generated by exposure of the photoacid generator to light. Besides, examples of the hole transport material include poly-TPD, polyvinyl carbazole (PVK), and poly [(9,9-dioctylfluorenyl-2,7-diyl)-co-(4,4′-(N-(4-sec-butylphenyl)) diphenylamine)] (TFB). These hole transport materials may be used as a dispersion liquid or a solution for forming the hole transport layer, for example.

The dispersion liquid of the hole injection material and the dispersion liquid of the hole transport material may include, for example, a polar solvent such as ethanol. Examples of the polar solvent include a polar solvent having an SP value of less than 12.0 and a polar term of less than 5.0 as in the dispersion liquid of quantum dots (QDs). According to the positive-working photosensitive composition and the method for manufacturing a light-emitting element according to an embodiment of the disclosure, not only the solvent resistance to the solvent contained in the dispersion liquid of quantum dots (QDs) but also the polar solvent resistance to the solvent contained in the dispersion liquid of the hole injection material and the dispersion liquid of the hole transport material is enhanced.

All the light-emitting layers including the above-described light-emitting layers 70R, 70B, and 70G emit light by recombination of positive holes transported from the first electrodes or the second electrodes with electrons. In the present embodiment, the light-emitting layers are quantum dot light-emitting layers including quantum dots (QDs: semiconductor nanoparticles) of different colors as a light-emitting material, but are not limited thereto and may be an organic light-emitting diode (OLED).

The color of light emitted from each light-emitting layer varies depending on the light emission central wavelength. Note that, in the present embodiment, the quantum dots of the plurality of types are combinations of the red quantum dots, the green quantum dots, and the blue quantum dots, but the quantum dots need not necessarily be one of those combinations.

Each light-emitting layer may include, for example, a continuous film of a metal sulfide and a plurality of quantum dots included in the continuous film. The metal sulfide may be, for example, a sulfide semiconductor of ZnS (zinc sulfide), ZnTeS, ZnMgS₂, MgS, Ga₂S₃, ZnGa₂S₄, or MgGa₂S₄. The continuous film may have an area of 1000 nm² or more in a plane direction orthogonal to the thickness direction at any position in the thickness direction of each light-emitting layer, for example. The average thickness of each light-emitting layer may be 10 nm or more and 100 nm or less, and the maximum value of the thickness of each light-emitting layer may be equal to or less than twice the minimum value thereof.

Each of the quantum dots (QDs) included in each light-emitting layer may have, for example, a core structure, a core/shell structure, a core/shell/shell structure, or a core/shell with continuously varying ratio structure. In a case where the quantum dot (QD) has a core structure, ligands are provided on the surface of the core, and in a case where the quantum dot (QD) has a structure having a shell, the ligands are provided on the surface of the shell. The core portion of the quantum dot (QD) may be composed of, for example, Si, C, or the like in a case of a unitary system, composed of, for example, CdSe, CdS, CdTe, InP, GaP, InN, ZnSe, ZnS, ZnTe, or the like in a case of a binary system, composed of, for example, CdSeTe, GaInP, ZnSeTe, or the like in a case of a ternary system, and composed of, for example, AIGS or the like in a case of a quaternary system. The shell portion can be composed of, for example, CdS, CdTe, CdSe, ZnS, ZnSe, ZnTe, or the like in a case of a binary system, and composed of, for example, CdSSe, CdTeSe, CdSTe, ZnSSe, ZnSTe, ZnTeSe, AIP, or the like in a case of a ternary system.

Note that the quantum dot (QD) is a dot having a maximum width of 100 nm or less. A shape of the quantum dot (QD) is not limited to a specific shape as long as it is within a range satisfying the maximum width, and is not limited to a spherical three-dimensional shape (circular cross-sectional shape). The shape may be, for example, a polygonal cross-sectional shape, a rod-shaped three-dimensional shape, a branch-shaped three-dimensional shape, or a three-dimensional shape having unevenness on the surface thereof, or a combination of them.

The ligand included in the quantum dot (QD) may be an inorganic ligand or an organic ligand. In a case where the ligand included in the quantum dot (QD) is an organic ligand, the organic ligand may be an organic compound including a functional group such as amine or thiol. The quantum dot (QD) may include the inorganic ligand described above and may further include an organic ligand. In a case where the ligand included in the quantum dot (QD) is an inorganic ligand, the ligand may be, for example, a halogen ligand including a halogen atom. In this case, the average value of the concentration of halogen atoms within the distance of 1 nm from the outermost surface of each of the quantum dots (QDs) may be 10%, 50%, or 100% higher than the average value of the concentration of halogen atoms at other positions.

The light-emitting layer can be film-formed by separately patterning for each subpixel by using a dispersion liquid in which quantum dots are dispersed by a spin coating method, an ink-jet method, or the like. The dispersion liquid of quantum dots contains a solvent such as n-hexane, toluene, or phenylcyclohexane, and may be mixed with a dispersion material such as thiol or amine.

In a case where the light-emitting material of the light-emitting layer contains a quantum dot having a shell of a metal sulfide which is a sulfide semiconductor as an inorganic ligand, the quantum dot only need be produced in an inert gas atmosphere as follows.

First, to obtain a precursor of the sulfide semiconductor, a dispersion liquid containing a metal acetate, a metal nitrate, a metal halide, or the like as a metal source and thiourea, N-methylthiourea, or 1,3-dimethylthiourea as a sulfur source is prepared. The dispersion liquid may contain, as a precursor, a metal complex in which thiourea, N-methylthiourea, 1,3-dimethylthiourea, N,N′-dimethylthiourea, tetramethylthiourea, or thioacetamide is coordinated to a metal atom.

Next, a polar solvent in which halide ions in an excessive amount relative to the quantum dots are dissolved is mixed with a non-polar solvent in which the quantum dots to which carbon chains as organic ligands are coordinated are dispersed, and the organic ligands of the quantum dots are substituted with halide ions. Subsequently, the dispersion liquid of the precursor of the sulfide semiconductor and the dispersion liquid of the quantum dots in which the organic ligands are substituted with the halide ions are mixed and stirred.

The polar solvent for producing the quantum dots may contain, for example, at least one of polar solvents such as dimethyl sulfoxide (DMSO) and N,N-dimethylformamide (DMF), esters or lactones such as methyl acetate, ethers such as tetrahydrofuran, tetrahydrothiophene, and diethyl sulfide. The non-polar solvent is desirably, for example, toluene, hexane, octane, octadecene, or the like, and is preferably a non-polar solvent which is not mixed with the polar solvent for producing the quantum dots.

In a case where the polar solvent in the dispersion liquid of the precursor of the sulfide semiconductor and the non-polar solvent in the dispersion liquid of the quantum dots substituted with the halide ions are separated into two phases, the quantum dots each including a shell of the sulfide semiconductor as the inorganic ligand can be generated in the phase of the polar solvent. As described above, the obtained quantum dots may be dispersed in a polar solvent to be used for forming a light-emitting layer.

The dispersion liquid of the polar solvent containing the quantum dots is applied onto the substrate, and the layered body is heated at 80° C. to 500° C. to form a light-emitting layer containing the quantum dots each having a shell of the sulfide semiconductor as an inorganic ligand.

The electron transport layer is a layer that transports electrons toward the light-emitting layer. Although not illustrated, an electron injection layer may be formed between the electron transport layer and the cathode. Examples of the electron injecting material contained in the electron injection layer include LiF.

The electron transporting material contained in the composition used for forming the electron transport layer is not particularly limited as long as it is an electron transporting material capable of stabilizing the transport of electrons to the light-emitting layer, and examples thereof include nanoparticles of ZnO, ZnS, ZrO, MgZnO, AlZnO, TiO₂, or the like, and these nanoparticles may include ligands such as organic ligands and inorganic ligands on their surfaces. These compositions may be collectively applied to subpixels in a plurality of light-emitting elements by a spin coating method, a dip coating method, or the like, or may be separately applied to each subpixel by an ink-jet method or the like.

Here, the dispersion liquid of the electron transporting material may contain, for example, a polar solvent such as ethanol, and examples of the polar solvent include a polar solvent having an SP value of less than 12.0 and a polar term of less than 5.0, similarly to the dispersion liquid of quantum dots (QDs). According to the positive-working photosensitive composition and the method for manufacturing a light-emitting element according to an embodiment of the disclosure, not only the polar solvent resistance to the solvent contained in the dispersion liquid of quantum dots (QDs) but also the polar solvent resistance to the solvent contained in the dispersion liquid of the electron transporting material is enhanced. The electron transporting material is used as a dispersion liquid for forming the electron transport layer.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### EXAMPLE

An example of the disclosure will be described below.

### [1] Preparation of Resin Composition

Sample compositions were prepared using the materials shown in the following [Materials] section.

### Materials

### Water-Soluble Resin

PVA-PVP graft copolymer A-1
PVA ratio: 0.3
PVA-PVP graft copolymer A-2
PVA ratio 0.4
PVA-PVP graft copolymer A-3
PVA ratio 0.5
PVA-PVP graft copolymer B-1
PVA ratio: 0.6
PVA-PVP graft copolymer B-2
PVA ratio 0.7
PVA-PVP graft copolymer B-3
PVA ratio 0.8
Polyvinyl alcohol (PVA)-1
Polyvinylpyrrolidone (PVP)-1

The PVA ratio in the water-soluble resin was calculated based on the following equation.

$$PVA ratio = PVA / ( PVA + PVP )$$

PVA: Molar amount of a monomer unit constituting a PVA polymer unit
PVP: Molar amount of a monomer unit constituting a PVP polymer unit
“PVA-PVP graft copolymer A” means a graft copolymer in which a hydroxyl group of PVA in PVA-PVP is substituted with a hydrophobic group, and “PVA-PVP graft copolymer B” means a pure PVA-PVP graft copolymer in which a hydroxyl group of PVA is not substituted with a hydrophobic group.

### Positive-Working Photosensitizer

### Positive-Working Photosensitizer A:

1,2-diazonaphthoquinone sulfonic acid ester of 2,3,4-trihydroxybenzophenone;

### Positive-Working Photosensitizer B:

1,2-diazonaphthoquinone sulfonic acid ester of 2,3,4,4′-tetrahydroxybenzophenone;

### Positive-Working Photosensitizer C:

6-diazo-5,6-dihydro-5-oxo-1-naphthalene sulfonic acid ester of 4,4′-(1-{4-[1-(4-hydroxyphenyl)-1-methylethyl]phenyl}ethylidene)diphenol

In any of the positive-working photosensitizers A to C, the conversion rate to the sulfonic acid ester was substantially 100%.

### Another Material

Solvent: Dimethyl sulfoxide (DMSO)

### [2] Evaluation of Photoresist Layer

### [2-1] Evaluation of Positive-Working Photosensitizer

5 g of the PVA-PVP graft copolymer A-2 was weighed and dissolved in 100 mL of DMSO to obtain a solution of a water-soluble resin. A composition of Sample 7 (Comparative Example) was prepared using this. Subsequently, for solutions prepared by the same methods as the composition of Sample 7, under a light-shielding condition, the positive-working photosensitizers A to C were mixed at a mass ratio of the solutions and the positive-working photosensitizers of 17:3 (15 mass % addition) or 7:3 (30 mass % addition) to prepare the positive-working photosensitive compositions of Samples 1 to 6 in such a manner that the addition amounts of the positive-working photosensitizers were the addition amounts shown in Table 1, respectively.

Sample 1 was applied onto a glass substrate (2.5 cm×2.5 cm) by a spin coating method, and then dried by heating at 80° C. for 3 minutes. Thus, a photoresist layer was formed of the positive-working photosensitive composition of Sample 1 on the glass substrate. Subsequently, photoresist layers of the positive-working photosensitive compositions of Samples 2 to 6 and a layer of Sample 7 for comparison were formed as individual samples on glass substrates by the same procedure as in Sample 1. The film thickness of each of the photoresist layers of Samples 1 to 6 and the layer of Sample 7 for comparison was about 1 μm.

Subsequently, the layers were immersed in an alkaline aqueous solution (0.8 mass % TMAH) as a treatment liquid at a room temperature of 23° C. for 30 seconds, then taken out, and dried by N₂ blow. Thereafter, the film thicknesses of the photoresist layers were measured again. Table 1 shows the positive-working photosensitizers contained in the photosensitive compositions of Samples 1 to 7, the addition amounts, and the evaluation results of the film thickness reduction amounts.

TABLE 1

| | | Addition | Alkaline aqueous |
|---|---|---|---|
| | Positive-working | amount | solution film thickness |
| | photosensitizer | (mass %) | reduction amount (nm) |
| Sample 1 | A | 15 | 720 |
| Sample 2 | A | 30 | 358 |
| Sample 3 | B | 15 | 750 |
| Sample 4 | B | 30 | 376 |
| Sample 5 | C | 15 | 295 |
| Sample 6 | C | 30 | 147 |
| Sample 7 | — | — | 1700 or more |
| (Comparative | | | |
| Example) | | | |

In all of Samples 1 to 6, the reduction in film thickness was more strongly suppressed in 30 mass % addition than in 15 mass % addition. It was confirmed that when the addition amount was larger, the number of sites subjected to diazo coupling in the unexposed portion tended to increase. Thus, it can be determined that the film thickness residual rate of the unexposed portion desired to be left after exposure to light can be increased as the polar solvent resistance, and clear patterning can be formed as the developability.

### [2-2] Evaluation of Peeling Easiness

The positive-working photosensitive composition of Sample 6 was separately prepared, applied onto a glass substrate (2.5 cm×2.5 cm) by a spin coating method under a light-shielding condition, and then dried by heating at 80° C. for 3 minutes. Thus, a photoresist layer was formed of the positive-working photosensitive composition of Sample 6 on the glass substrate. Similarly, as Sample 6C for comparison, a negative-working photoresist layer was prepared in accordance with the same procedure as in the case of the positive-working photosensitive composition of Sample 6 except that a negative-working photosensitive composition available from T Company was used. The thickness of each of the photoresist layer of the positive-working photosensitive composition of Sample 6 and the negative-working photoresist layer of Sample 6C was about 2 μm. The composition of the negative-working photosensitive composition available from T Company is as follows.
Acrylic resin: 40 mass %
Photoinitiator: 5 mass %
Solvent 1 PGMEA: 50 mass %,
Solvent 2 isopropanol: 5 mass %

Next, the positive-working photoresist layer formed of the positive-working photosensitive composition of Sample 6 and the negative-working photoresist layer formed of the negative-working photosensitive composition of Sample 6C for comparison were each evaluated for peeling easiness after pattern formation. In the evaluation of the peeling easiness, for the positive-working photoresist layer of Sample 6, a photoresist layer outside the pattern was formed on the glass substrate in the unexposed portion under the condition of no exposure to light, and for the negative-working photoresist layer of Sample 6C, a photoresist layer outside the pattern was formed on the glass substrate by exposure to g-line under the condition of an exposure amount of 240 mJ/cm².

Each of the photoresist layers of Samples 6 and 6C was immersed in DMSO at room temperature of about 23° C. for 60 seconds, then taken out, and subjected to N₂ blow drying at room temperature of 23° C. Thereafter, the thicknesses of the photoresist layers of Samples 6 and 6C were measured. Then, the dissolution rate in water was calculated based on the difference between the thickness before immersion and the thickness after immersion, and the immersion time in DMSO. Table 2 shows the evaluation results of the dissolution rates of the photoresist layers of Samples 6 and 6C in DMSO.

TABLE 2

| | Photoresist | Dissolution rate |
|---|---|---|
| | layer type | in DMSO (nm/s) |
| Sample 6 | Positive-working | 60 |
| Sample 6C (Comparative | Negative-working | 5 |
| Example) | | |

As shown in Table 2, it was confirmed that the photoresist layer formed of the positive-working photosensitive composition of Sample 6 as a positive-working photoresist layer had higher peeling and removing properties with DMSO (SP value: 12.8, polar term: 7.2) than those of the negative-working photoresist layer of Sample 6C, and it was possible to more rapidly perform peeling and developing after patterning.

### [2-3] Evaluation of Water-Soluble Resin

A layer of a water-soluble resin contained in a photoresist layer was prepared using Samples 8 to 13 as Reference Examples and Samples 14 and 15 as Comparative Examples, and the dissolution rate in water was evaluated. First, 5 g of the PVA-PVP graft copolymer A-1 was weighed and dissolved in 100 mL of DMSO to obtain a solution of the PVA-PVP graft copolymer A-1. A composition of Sample 8 was prepared using this.

A water-soluble resin composition of Sample 9 was prepared in accordance with the same procedure as that of the water-soluble resin composition of Sample 8 except that the PVA-PVP graft copolymer A-1 was changed to the PVA-PVP graft copolymer A-2. Similarly, water-soluble resin compositions of Samples 10 to 15 were prepared by changing the PVA-PVP graft copolymer A-1 to the PVA-PVP graft copolymer A-3, the PVA-PVP graft copolymer B-1, the PVA-PVP graft copolymer B-2, the PVA-PVP graft copolymer B-3, polyvinyl alcohol-1, and polyvinyl pyrrolidone-1, respectively.

The water-soluble resin compositions of Samples 8 to 15 were each applied onto a glass substrate (2.5 cm×2.5 cm) by a spin coating method, and then dried by heating at 80° C. for 3 minutes.

Each of the water-soluble resin layers contained in photoresist of Samples 8 to 15 was immersed in pure water (room temperature of about 23° C.) for 60 seconds, then taken out, and subjected to N₂ blow drying at room temperature of 23° C. Thereafter, a thickness of each of the water-soluble resin layers for photoresist was measured. Then, the dissolution rate in water was calculated based on the difference between the thickness before immersion and the thickness after immersion, and the immersion time in pure water. Table 3 shows the evaluation results of the water-soluble resins contained in the water-soluble resin layers for photoresist of Samples 8 to 15, the PVA ratios, and the dissolution rates in water.

TABLE 3

| | | PVA | Dissolution rate |
|---|---|---|---|
| | Water-soluble resin | ratio | in water (nm/s) |
| Sample 8 | PVA-PVP graft copolymer A-1 | 0.3 | 100 or more |
| Sample 9 | PVA-PVP graft copolymer A-2 | 0.4 | 50 |
| Sample 10 | PVA-PVP graft copolymer A-3 | 0.5 | 100 or more |
| Sample 11 | PVA-PVP graft copolymer B-1 | 0.6 | 100 or more |
| Sample 12 | PVA-PVP graft copolymer B-2 | 0.7 | 70 |
| Sample 13 | PVA-PVP graft copolymer B-3 | 0.8 | 50 |
| Sample 14 | Polyvinyl alcohol-1 | 1.0 | 30 or less |
| (Comparative | | | |
| Example) | | | |
| Sample 15 | Polyvinylpyrrolidone-1 | — | 1000 or more |
| (Comparative | | | |
| Example) | | | |

As shown in Table 3, it was confirmed that in the water-soluble resin layers for photoresist of Samples 8 to 13, the dissolution rate in water was 50 nm/s or more, and the higher the PVA ratio, the more preferable from the viewpoint of thickness control. In addition, in Samples 8 to 10 in which a part of PVA was derivatized, it was possible to suppress the dissolution rate in water due to the influence even though the PVA ratio was low as compared with Samples 11 to 13. On the other hand, the water-soluble resin layer of Sample 14 containing polyvinyl alcohol-1 had a low dissolution rate in water of 30 nm/s, and the water-soluble resin layer of Sample 15 containing polyvinylpyrrolidone-1 had a too high dissolution rate in water of 1000 nm/s. From these results, it is expected that the water-soluble resin used in the positive-working photosensitive composition is preferably a copolymer rather than a homopolymer having water solubility from the viewpoint of film thickness control, that is, developability and polar solvent resistance.

1. A composition comprising:
a water-soluble resin;
a positive-working photosensitizer; and
a solvent,
wherein the water-soluble resin includes a copolymer including a vinyl alcohol monomer unit and a monomer unit having water solubility.

2. The composition according to claim 1,
wherein the positive-working photosensitizer is at least one positive-working photosensitizer selected from the group consisting of a diazoquinone compound, a polyolefin sulfone, and a polyphthalaldehyde, and
the diazoquinone compound has a diazoquinone moiety bonded to an alcohol residue or an amine residue via an ester bond or an amide bond.

3. The composition according to claim 1,
wherein the copolymer is a graft copolymer or a block copolymer including a polymer unit obtained by polymerization of the vinyl alcohol monomer unit and a polymer unit having water solubility.

4. The composition according to claim 1,
wherein a content of the vinyl alcohol monomer unit included in the water-soluble resin is from 35 to 90 mol % or more.

5. The composition according to claim 3,
wherein the polymer unit having water solubility has an SP value calculated from an SP value of a monomer thereof of 25.8 or more.

6. The composition according to claim 1,
wherein the polymer unit having water solubility is one polymer unit selected from a polymer unit of one monomer unit selected from the group consisting of a monomer unit derived from N-vinylpyrrolidone, a monomer unit derived from (meth)acrylic acid, a monomer unit derived from (meth)acrylic acid salt, a monomer unit derived from (meth)acrylamide, and a monomer unit derived from N-vinylacetamide, and a polymer unit of a unit selected from an ethylene oxide unit and a propylene amine unit.

7. The composition according to claim 1,
wherein the polymer unit having water solubility is a polymer unit of a monomer unit derived from N-vinylpyrrolidone.

8. The composition according to claim 1,
wherein a content of the positive-working photosensitizer is 15 mass % or more, per 100 mass % of a total of the water-soluble resin and the positive-working photosensitizer.

9. The composition according to claim 1,
wherein a content of the positive-working photosensitizer is 50 mass % or more, per 100 mass % of a total of the water-soluble resin and the positive-working photosensitizer.

10. The composition according to claim 1,
wherein a content of the positive-working photosensitizer is 70 mass % or more, per 100 mass % of a total of the water-soluble resin and the positive-working photosensitizer.

11. The composition according to claim 2,
wherein the alcohol residue or the amine residue of the diazoquinone compound further includes a hydroxyl group or an amino group, and
a molar ratio of the diazoquinone moiety is 30 mol % or more, per 100 mol % of a total of the diazoquinone moiety, the hydroxyl group, and the amino group.

12. The composition according to claim 1, further comprising:
a fluorine-based surfactant.

13. The composition according to claim 1,
wherein a coating film formed of the composition has a dissolution rate in dimethyl sulfoxide of 10 nm/s or more.

14. The composition according to claim 1,
wherein a coating film formed of the composition has a dissolution rate in ethanol of 10 nm/s or less.

15. A method for manufacturing a light-emitting element on a substrate, the method comprising:
applying the composition including a water-soluble resin, a positive-working photosensitizer and a solvent, the water-soluble resin including a copolymer including a vinyl alcohol monomer unit and a monomer unit having water solubility;
exposing the applied composition to light;
cleaning the exposed composition with a developer to develop a pattern of the composition on the substrate;
forming a light-emitting layer on the substrate on which the pattern is developed; and
peeling and developing, with a solvent, the composition remaining on the substrate on which the light-emitting layer is formed,
wherein the solvent has a δ (solubility parameter) represented by the following equation (1) of 12.0 or more:
$$δ ( solubility parameter ) = {( {δ}_{d}^{2} + {δ}_{P}^{2} + {δ}_{h}^{2} )}^{1 / 2} , \qquad ( 1 )$$
where δ_{d} is a dispersion term, δ_{P} is a polar term, and on is a hydrogen bonding term.

16. The manufacturing method according to claim 15,
wherein the solvent has δ_{P} of 5.0 or more in the equation (1).

17. The manufacturing method according to claim 15,
wherein in the forming the light-emitting layer, the light-emitting layer is formed by applying a dispersion liquid including a light-emitting material and a dispersion solvent, and
the dispersion solvent includes a solvent in which δ (solubility parameter) represented by the equation (1) is less than 12.0.
